(19) United States
(12) Patent Application Publication
(10) Pub. No.: US 2018/0003952 A1
(43) Pub. Date: Jan. 4, 2018

(54) PROJECTION EXPOSURE DEVICE

(71) Applicant: V TECHNOLOGY CO., LTD., Kanagawa (JP)

(72) Inventor: Michinobu Mizumura, Kanagawa (JP)

(73) Assignee: V TECHNOLOGY CO., LTD., Kanagawa (JP)

(21) Appl. No.: 15/542,281

(22) PCT Filed: Jan. 6, 2016
(86) PCT No.: PCT/JP2016/050221

§ 371 Date: Jul. 7, 2017

(30) Foreign Application Priority Data
Jan. 9, 2015 (JP) 2015-003636

(51) Int. Cl. G02B 26/10; G02B 3/00; G03F 7/20

(52) U.S. Cl. CPC G02B 26/10; G03F 7/70241; G02B 3/0037; G03F 7/2008

(57) ABSTRACT

A projection exposure device projects exposure light onto a substrate via a microlens array. The projection exposure device includes a scanning exposure unit that moves the microlens array along a scanning direction from one end toward another end of the substrate, and a microlens array shift unit that moves the microlens array in a shift direction intersecting with the scanning direction during movement of the microlens array caused by the scanning exposure unit.

### TECHNICAL FIELD

The present invention relates to a projection exposure device using a microlens array.

### BACKGROUND ART

Conventionally, as an exposure device in which a projection exposure of a substrate is done with a mask pattern, there is well known one in which a microlens array is placed between a mask and a substrate (see PTL 1 below). This conventional technique, as shown in FIG. 1, provides a substrate stage J1 that supports a substrate W and a mask M formed with a pattern with which the substrate W is exposed. Between the substrate W and the mask M arranged at a set interval, there is arranged a microlens array MLA in which microlenses are arranged two-dimensionally. With this conventional technique, exposure light L is radiated from above the mask M, and light that has passed through the pattern (aperture) of the mask M is projected onto the substrate W by the microlens array MLA, and the pattern formed in the mask M is transferred to the substrate surface. In order for an exposure to be done on the substrate W of a large area, a scanning exposure with the exposure light L is done on the substrate W by fixing and arranging the microlens array MLA and an exposure light source, omitted in the drawing, and relatively moving the microlens array MLA in a scanning direction Sc perpendicular to the paper surface with respect to the mask M and the substrate W that have been integrated.

### RELATED ART LITERATURE

### Patent Literature

[PTL 1] Japanese Publication of Patent Application No. 2012-216728

When a defect or failure exists in a microlens array in such a projection exposure device, a phenomenon occurs in which the exposure amount is partially decreased by the defect or failure. Therefore, when an exposure is performed while scanning is done in one direction with the microlens array, an area in which the exposure amount is partially decreased is formed in a streak shape along the scanning direction, and the exposure is significantly non-uniform.

### SUMMARY OF INVENTION

One or more embodiments of the present invention can prevent a significant non-uniform exposure even in the case where a defect or failure exists in a microlens, in a projection exposure device with which a projection exposure with a mask pattern of a mask is done on a substrate while scanning is done in one direction with a microlens array.

A projection exposure device according to one or more embodiments of the present invention is provided with the following configuration.

A projection exposure device that projects exposure light onto a substrate via a microlens array includes: a scanning exposure unit that moves the microlens array along a scanning direction from one end toward another end of the substrate; and a microlens array shift unit that moves the microlens array in a shift direction intersecting with the scanning direction during movement of the microlens array caused by the scanning exposure unit.

### ADVANTAGEOUS EFFECTS OF INVENTION

With the projection exposure device according to one or more embodiments of the present invention having such a feature, a projection exposure of an entire surface of the substrate can be done without causing a significantly non-uniform exposure even in the case where a defect or failure exists in the microlens array, since a projection exposure is done while the microlens array is shifted in the direction intersecting with the scanning direction.

### BRIEF DESCRIPTION OF DRAWINGS

FIG. 1 is an illustration of a conventional technique.

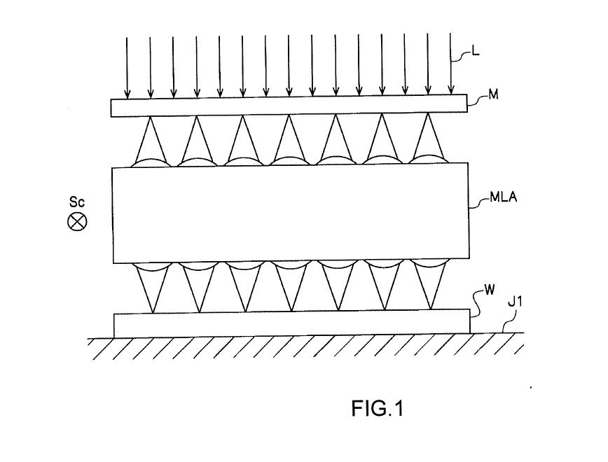

FIG. 2(a) and FIG. 2(b) are illustrations of a side view of a projection exposure device according to one or more embodiments of the present invention (FIG. 2(a) showing a state at the time of starting a scanning exposure, and FIG. 2(b) showing a state at the time of terminating the scanning exposure).

FIG. 3(a) and FIG. 3(b) are illustrations of a planar view of the projection exposure device according to one or more embodiments of the present invention (FIG. 3(a) showing a state at the time of starting a scanning exposure, and FIG. 3(b) showing a state at the time of terminating the scanning exposure).

FIG. 4(a) and FIG. 4(b) are illustrations showing an example of the form of a microlens array and a method of eliminating an non-uniform exposure (FIG. 4(a) being an example of a scanning exposure in which a microlens moves only in the scanning direction, and FIG. 4(b) being an example of a scanning exposure in which the microlens moves in the scanning direction and the shift direction).

FIG. 5(a) and FIG. 5(b) are graphs showing the results of scanning exposures in FIG. 4(a) and FIG. 4(b) (FIG. 5(a) being an example of the scanning exposure in which the microlens moves only in the scanning direction, and FIG. 5(b) being an example of the scanning exposure in which the microlens moves in the scanning direction and the shift direction).

### DESCRIPTION OF EMBODIMENTS

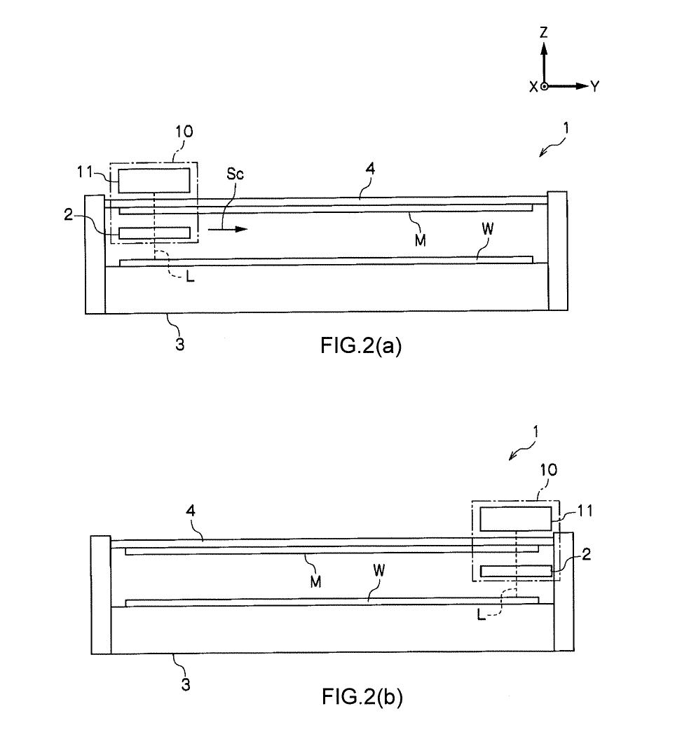

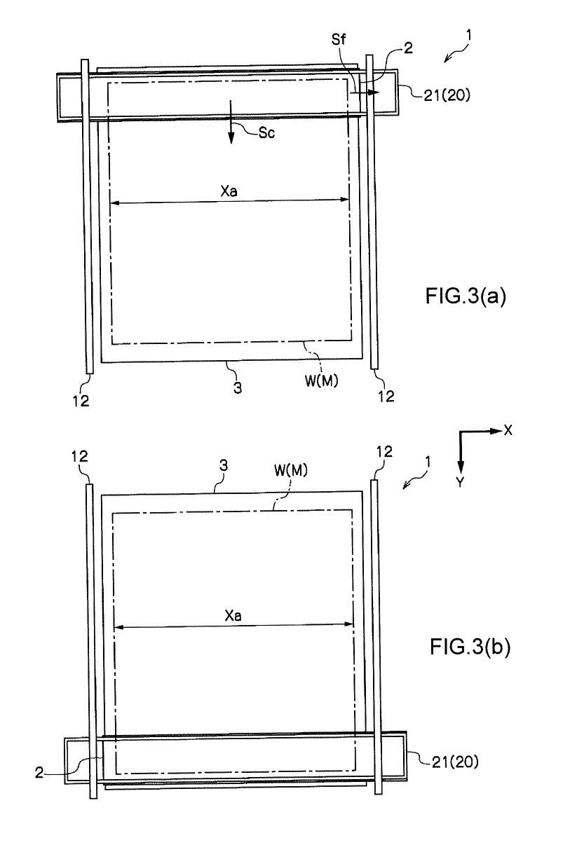

One or more embodiments of the present invention will be described below with reference to the drawings. FIGS. 2(a) and 2(b) and FIGS. 3(a) and 3(b) show a projection exposure device according to one or more embodiments of the present invention. FIGS. 2(a) and 2(b) are illustrations of a side view, and FIGS. 3(a) and 3(b) are illustrations of a planar view, where (a) indicates a state at the time of starting a scanning exposure and (b) indicates a state at the time of terminating the scanning exposure. In the drawings, the X-axis direction shows the width direction of a substrate, the Y-axis direction the longitudinal direction of the substrate, and the Z-axis direction the up-down direction.

A projection exposure device 1 is a device that projects the exposure light L onto the substrate W via a microlens array 2 and includes a scanning exposure unit 10 and a microlens array shift unit 20.

More specifically, the projection exposure device 1 includes a substrate supporter 3 that supports the substrate W and a mask supporter 4 that supports the mask M having a mask pattern with an aperture in a predetermined shape. The microlens array 2 is arranged between the substrate W supported by the substrate supporter 3 and the mask M supported by the mask supporter 4, so that a scanning projection exposure is performed through radiation of the exposure light L onto the substrate W via the microlens array 2.

The scanning exposure unit 10 includes the microlens array 2 described above and a light source 11 and, with the positional relationship of these fixed, is caused to move along the scanning direction Sc (Y-axis direction in the drawing). The scanning exposure unit 10 includes a scanning guide 12 for moving the microlens array 2 along the scanning direction Sc from one end to another end of the substrate W. The scanning guide 12 is provided along the longitudinal direction of the substrate W, on both sides of the substrate supporter 3 in the X-axis direction.

The exposure light L emitted from the light source 11 of the scanning exposure unit 10 transmits through an aperture part of the mask M and is radiated onto the substrate W via the microlens array 2. With the microlens array 2, the exposure light L that transmits through a part of the mask pattern forms an image on the substrate W. The microlens array 2, an imaging optical system, is a bi-telecentric lens of 1:1 magnification, for example. By moving the scanning exposure unit 10 in the scanning direction Sc and performing the scanning projection exposure, the mask pattern of the mask M is transferred onto an effective exposure surface of the substrate W.

During the movement of the microlens array 2 toward the scanning direction Sc caused by the scanning exposure unit 10, the microlens array shift unit 20 moves the microlens array 2 in a shift direction Sf intersecting with the scanning direction Sc. In order to perform such a movement of the microlens array 2, the microlens array shift unit 20 includes a shift guide 21. The shift guide 21 extends in the shift direction Sf (X-direction in the drawing) and, while itself moving in the scanning direction Sc along the scanning guide 12, moves the microlens array 2 in the shift direction Sf.

The length (length in the X-direction in the drawing) of the microlens array 2 supported by the microlens array shift unit 20 to be freely movable is configured to be longer, by not less than a set shift amount, than an effective exposure width Xa of the substrate W. The shift guide 21 includes a length in the X-direction necessary for moving the microlens array 2 by the set shift amount in the shift direction Sf.

The projection exposure device 1 including such a configuration performs a projection exposure with the mask pattern while moving the light source 11 and the microlens array 2 from one end to another end of the substrate W, from the time of starting the scanning exposure shown in FIG. 2(a) and FIG. 3(a) up to the state of the time of terminating the scanning exposure shown in FIG. 2(b) and FIG. 3(b).

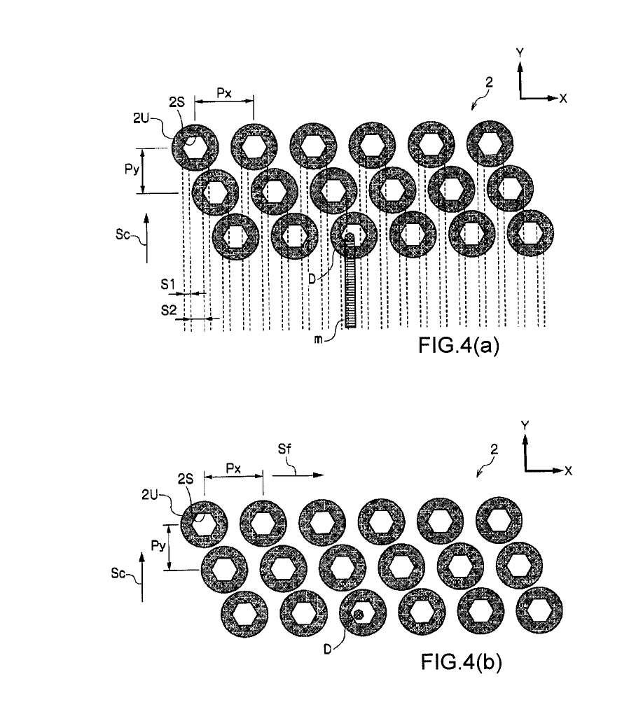

As shown in FIGS. 4(a) and 4(b), the microlens array 2 used in the projection exposure device 1 is covered by a light⁻shielding film, except for an effective exposure area of each of single lenses 2U. In the effective exposure area, a hexagonal-shaped field diaphragm (hexagonal field diaphragm 2S) is formed. A plurality of the single lenses 2U of the microlens array 2 are aligned in the X- and Y-axis directions, with pitch intervals pₓ in the alignment in the X-axis direction in the drawing, pitch intervals p_{y} in the alignment in the Y-axis direction in the drawing, and three rows as one group such that X-axis direction widths S1 of triangular portions in the hexagonal field diaphragms 2S are caused to overlap.

With such an alignment with three rows as one group, the exposure amount with the X-axis direction width 51 in the triangular portion in the hexagonal field diaphragm 2S and the exposure amount with an X-axis direction width S2 in a rectangular portion in the hexagonal field diaphragm 2S are made uniform, and an non-uniform exposure does not occur at a joining part of the single lenses 2U. As a dimension example of the hexagonal field diaphragm 2S in the single lens 2U, there are shown the pitch intervals pₓ=p_{y}=150 μm, the X-axis direction width S1 of the triangular portion=20 μm, and the X-axis direction width S2 of the rectangular portion=30 μm.

As shown in FIG. 4(a), when the scanning exposure is performed while the microlens array 2 is moved only in the scanning direction Sc, the amount of transmitted light partially decreases, in the case where one or a plurality of defective parts D exist in the single lenses 2U, in the defective part D. Therefore, a significant and line-shaped non-uniform exposure m is formed along the scanning direction Sc. In contrast, with the projection exposure device 1 according to one or more embodiments of the present invention, the microlens array 2 is not only moved in the scanning direction Sc but also moved in the shift direction Sf to perform the scanning exposure, as shown in FIG. 4(b). Therefore, an area exposed to light transmitting through the defective part D is dispersed in the shift direction Sf, and the occurrence of a significant and line-shaped non-uniform exposure m can be avoided.

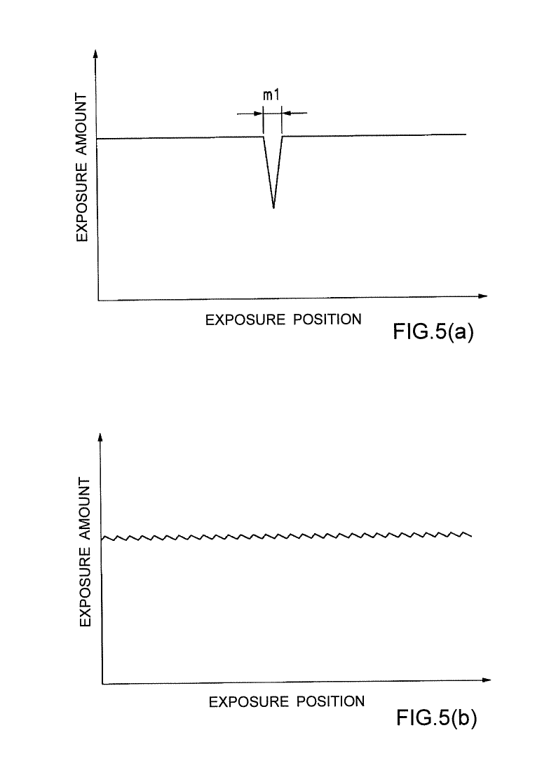

FIGS. 5(a) and 5(b) are graphs showing the results of the scanning exposure in FIG. 4(a) and FIG. 4(b) and show exposure amounts in exposure positions along the X-axis direction. With the scanning exposure in which the microlens array 2 is moved only in the scanning direction Sc as shown in FIG. 4(a), the obtained exposure amounts are uniform in exposure positions in which the defective part D does not exist, but an exposure-amount decreased area with a width ml is formed in a streak shape in an exposure position in which the defective part D exists, as shown in FIG. 5(a).

In contrast, when the scanning exposure is performed with the microlens array 2 being not only moved in the scanning direction Sc but also moved in the shift direction Sf in the example as shown in FIG. 4(b), a displacement occurs in an overlap of the triangular portions of the hexagonal field diaphragms, causing slight variations in the exposure amounts in an entire exposure position, as shown in FIG. 5(b). However, the exposure-amount decreased area is smoothed by the movement of the microlens array 2 in the shift direction Sf, and a significant and line-shaped non-uniform exposure is eliminated.

The shift amount of the microlens array 2 in the case of exposing the entire effective exposure area of the substrate can be set appropriately through the width m1 of the exposure-amount decreased area described earlier. Basically, a line-shaped non-uniform exposure can be eliminated effectively with a shift amount equivalent to the width m1 of the exposure-amount decreased area. The shift amount is set such that, as a specific result, the difference of the maximum exposure amount and the minimum exposure amount is not more than 2% of the average exposure amount of the entire exposure position.

One or more embodiments of the present invention has been described above in detail with reference to the drawings. However, the specific configuration is not limited to thereto. Changes in design or the like that are made without departing from the gist of the present invention are included in the present invention. One or more embodiments of the present invention described above, unless a configuration, or the like thereof has a particular inconsistency may be combined through application of a technique in one to another.

### EXPLANATION OF REFERENCE NUMERALS

1 Projection exposure device
2 Microlens array
2U Single lens
2S Hexagonal field diaphragm
3 Substrate supporter
4 Mask supporter
10 Scanning exposure unit
11 Light source
12 Scanning guide
20 Microlens array shift unit
21 Shift guide
L Exposure light
W Substrate
M Mask
Sc Scanning direction
Sf Shift direction
Xa Effective exposure width
D Defective part
m Non-uniform exposure
pₓ, p_{y} Pitch interval

1. A projection exposure device that projects exposure light onto a substrate via a microlens array, the projection exposure device comprising:
a scanning exposure unit that moves the microlens array along a scanning direction from one end toward another end of the substrate; and
a microlens array shift unit that moves the microlens array in a shift direction intersecting with the scanning direction during movement of the microlens array caused by the scanning exposure unit.

2. The projection exposure device according to claim 1, wherein a shift amount by which the microlens array shift unit moves the microlens array while the scanning exposure unit moves the microlens array from one end to another end of the substrate is set in accordance with a width of an exposure-amount decreased area that is created in a case where the microlens array is moved only by the scanning exposure unit.

3. The projection exposure device according to claim 2, wherein the shift amount is set such that a difference between a maximum exposure amount and a minimum exposure amount is not more than 2% with respect to an average exposure amount of an entire exposure position orthogonal to the scanning direction.

4. A projection exposure method, comprising:
projecting exposure light onto a substrate via a microlens array; and
moving the microlens array in a direction intersecting with a scanning direction upon performing a scanning exposure while moving the microlens array along the scanning direction from one end toward another end of the substrate.
